(19) United States
(12) Patent Application Publication
(10) Pub. No.: US 2026/0045215 A1
(43) Pub. Date: Feb. 12, 2026

(54) PIXEL, DISPLAY DEVICE, AND ELECTRONIC DEVICE INCLUDING THE SAME

(71) Applicant: Samsung Display Co., Ltd., Yongin-si (KR)

(72) Inventors: Hee Rim SONG, Yongin-si (KR); Cheol Gon LEE, Yongin-si (KR); Mu Kyung JEON, Yongin-si (KR)

(21) Appl. No.: 19/194,959

(22) Filed: Apr. 30, 2025

(30) Foreign Application Priority Data
Aug. 6, 2024 (KR) 10-2024-0104556

(51) Int. Cl. G09G 3/3233; G06V 40/13; G09G 3/32

(52) U.S. Cl. CPC G09G 3/3233; G06V 40/1318; G09G 3/32; G09G 2300/0819; G09G 2300/0842; G09G 2300/0861; G09G 2310/08; G09G 2354/00; G09G 2360/14

(57) ABSTRACT

A pixel of the disclosure includes a light-emitting element, a first transistor connected between a first power voltage and the light-emitting element, and configured to control a current flowing through the light-emitting element, and a light-receiving element connected between a fifth node and a second power voltage, wherein a voltage of the fifth node corresponds to a light amount applied to the light-receiving element, and wherein a current transmitted to a readout line through the first transistor corresponds to the voltage of the fifth node.

### CROSS-REFERENCE TO RELATED APPLICATION

The present application claims priority to, and the benefit of, Korean Patent Application No. 10-2024-0104556, filed on Aug. 6, 2024, in the Korean Property Office, the entire disclosure of which is incorporated herein by reference.

### BACKGROUND

### 1. Field

The disclosure relates to a pixel, a display device, and an electronic device including the same.

### 2. Description of the Related Art

As information technology develops, importance of a display device, which is a connection medium between a user and information, is emerging. In response to this, a use of a display device, such as a liquid crystal display device and an organic light-emitting display device is increasing. In addition, the display device may sense a user's fingerprint using a light sensor and perform a user authentication function.

### SUMMARY

Embodiments provide a pixel, a display device, and an electronic device including the same capable of implementing a light sensor with fewer transistors.

According to one or more embodiments of the disclosure, a pixel includes a light-emitting element, a first transistor connected between a first power voltage and the light-emitting element, and configured to control a current flowing through the light-emitting element, and a light-receiving element connected between a fifth node and a second power voltage, wherein a voltage of the fifth node corresponds to a light amount applied to the light-receiving element, and wherein a current transmitted to a readout line through the first transistor corresponds to the voltage of the fifth node.

The first transistor may include a control electrode connected to a first node, a first electrode connected to a fourth node, and a second electrode connected to a second node, wherein the pixel further includes a ninth transistor connected between the second node and the fifth node, and a tenth transistor connected between a reset voltage and the fifth node.

The pixel may further include an eighth transistor connected between the fourth node and the readout line.

The pixel may further include a second transistor connected between the fourth node and a data line.

The pixel may further include a storage capacitor connected between the first power voltage and the first node.

The pixel may further include a third transistor connected between the first node and the second node.

The light-emitting element may include an anode electrode connected to a third node, and a cathode electrode connected to the second power voltage, wherein the pixel further includes a fifth transistor connected between the first power voltage and the fourth node, and a sixth transistor connected between the second node and the third node.

The pixel may further include a fourth transistor connected between the first node and a first initialization voltage, and a seventh transistor connected between the third node and a second initialization voltage.

According to one or more other embodiments of the disclosure, a display device includes a display panel including pixels, and a display panel driver configured to drive the display panel, wherein the pixels include a light-emitting element, a first transistor connected between a first power voltage and the light-emitting element, and configured to control a current flowing through the light-emitting element, and a light-receiving element connected between a fifth node and a second power voltage, wherein a voltage of the fifth node is changed according to a light amount applied to the light-receiving element, and a current corresponding to the voltage of the fifth node is transmitted to the display panel driver through the first transistor.

The first transistor may include a control electrode connected to a first node, a first electrode connected to a fourth node, and a second electrode connected to a second node, wherein the pixels further include a ninth transistor connected between the second node and the fifth node, and a tenth transistor connected between a reset voltage and the fifth node.

The display device may further include an eighth transistor connected between the fourth node and a corresponding transmission/reception line.

The display device may further include switches configured to selectively connect a transmission/reception line corresponding to one or more of the pixels to one of a bias voltage line or a readout line corresponding to the one or more pixels, and a readout circuit connected to the readout line.

The pixels may further include a second transistor connected between the fourth node and a data line.

The pixels may further include a storage capacitor connected between the first power voltage and the first node.

The pixels may further include a third transistor connected between the first node and the second node.

The light-emitting element may include an anode electrode connected to a third node, and a cathode electrode connected to the second power voltage, wherein the pixels further include a fifth transistor connected between the first power voltage and the fourth node, and a sixth transistor connected between the second node and the third node.

The pixels may further include a fourth transistor connected between the first node and a first initialization voltage, and a seventh transistor connected between the third node and a second initialization voltage.

The pixels may further include a second transistor connected between the fourth node and a data line, wherein the pixels further include a third transistor connected between the first node and the second node, wherein the first, second, fifth, sixth, seventh, eighth, and ninth transistors include PMOS transistors, and wherein the third, fourth, and tenth transistors include NMOS transistors.

According to still one or more other embodiments of the disclosure, an electronic device includes a processor configured to provide input image data to a display device that is configured to display an image based on the input image data, and a power supply configured to supply power to the display device, wherein the display device includes a display panel including pixels, and a display panel driver configured to drive the display panel, wherein the pixels include a light-emitting element, a first transistor connected between a first power voltage and the light-emitting element, and configured to control a current flowing through the light-emitting element, and a light-receiving element connected between a fifth node and a second power voltage, wherein a voltage of the fifth node is changed according to a light amount applied to the light-receiving element, and wherein a current corresponding to the voltage of the fifth node is transmitted to the display panel driver through the first transistor.

The first transistor may include a control electrode connected to a first node, a first electrode connected to a fourth node, and a second electrode connected to a second node, wherein the pixels further include a ninth transistor connected between the second node and the fifth node, and a tenth transistor connected between a reset voltage and the fifth node.

According to the pixel, the display device, and the electronic device including the same, according to the disclosure, a light sensor may be implemented with fewer transistors.

### BRIEF DESCRIPTION OF THE DRAWINGS

The above and other aspects of the disclosure will become more apparent by describing in further detail embodiments thereof with reference to the accompanying drawings, in which:

FIG. 1 is a block diagram illustrating a display device according to embodiments of the disclosure;

FIG. 2 is a circuit diagram illustrating one or more embodiments of a sub-pixel and a light sensor shown in FIG. 1;

FIG. 3 is a timing diagram illustrating an example in which the display device of FIG. 1 drives the light sensor;

FIG. 4 is a circuit diagram illustrating one or more embodiments of a sub-pixel according to one or more embodiments of the disclosure;

FIG. 5 is a timing diagram illustrating one or more embodiments of a method of driving the sub-pixel shown in FIG. 4;

FIG. 6 is a diagram illustrating one or more embodiments of a connection structure of a transmission/reception line LX;

FIG. 7 is a diagram illustrating one or more other embodiments of the connection structure of the transmission/reception line LX;

FIG. 8 is a block diagram illustrating an electronic device according to embodiments of the disclosure;

FIG. 9 is a diagram illustrating an example in which an electronic device of FIG. 8 is implemented as a smartphone; and

FIG. 10 is a diagram illustrating an example in which an electronic device of FIG. 8 is implemented as a tablet PC.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B”may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),”etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure. ” Furthermore, the expression “being the same” may mean “being substantially the same”. In other words, the expression “being the same” may include a range that can be tolerated by those of ordinary skill in the art. The other expressions may also be expressions from which “substantially”has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

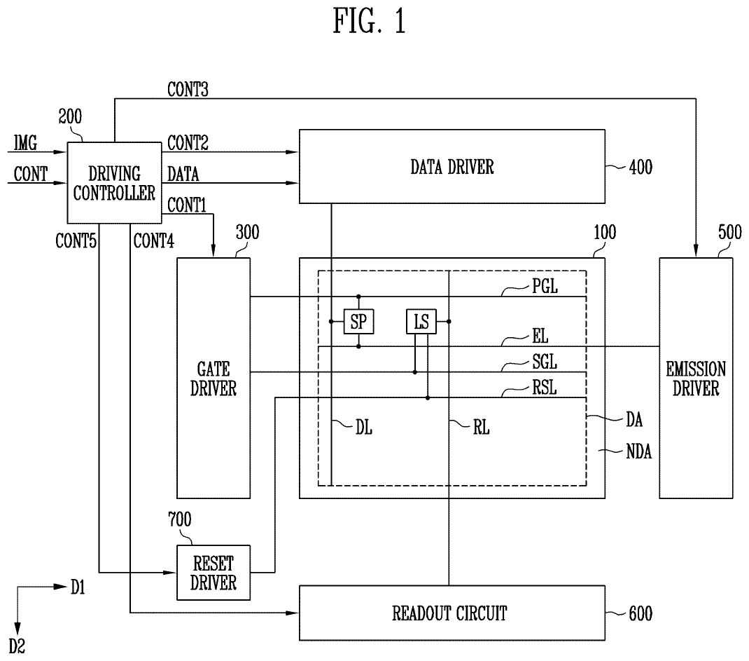

FIG. 1 is a block diagram illustrating a display device according to embodiments of the disclosure.

Referring to FIG. 1, the display device may include a display panel 100 and a display panel driver. The display panel driver may include a driving controller 200, a gate driver 300, a data driver 400, an emission driver 500, a readout circuit 600, and a reset driver 700. In one or more embodiments, the driving controller 200 and the data driver 400 may be integrated into one chip.

The display panel 100 may include a display area DA for displaying an image, and a non-display area NDA adjacent to the display area DA. In one or more embodiments, the gate driver 300 and the emission driver 500 may be mounted in the non-display area NDA.

The display panel 100 may include a plurality of pixel gate lines PGL, a plurality of data lines DL, a plurality of emission lines EL, and a plurality of sub-pixels SP electrically connected to the pixel gate lines PGL, the data lines DL, and the emission lines EL. The pixel gate lines PGL and the emission lines EL may extend in a first direction D1, and the data lines DL may extend in a second direction D2 crossing the first direction D1.

The display panel 100 may include a plurality of sensing gate lines SGL, a reset line RSL, a plurality of readout lines RL, and a plurality of light sensors LS electrically connected to the plurality of sensing gate lines SGL, the reset line RSL, and the readout lines RL.

In one or more embodiments, the sensing gate lines SGL are connected to the gate driver 300, but the disclosure is not limited thereto. For example, the display panel driver may include a separate driver that drives the sensing gate lines SGL.

In one or more embodiments, the reset lines RSL are connected to the reset driver 700, but the disclosure is not limited thereto. For example, the reset lines RSL may be driven by a separate driver that drives the gate driver 300, the emission driver 500, or the sensing gate lines SGL rather than the reset driver 700.

The driving controller 200 may receive input image data IMG and an input control signal CONT from a processor (for example, a graphic processing unit (GPU) or the like). For example, the input image data IMG may include red image data, green image data, and blue image data. In one or more embodiments, the input image data IMG may further include white image data. As another example, the input image data IMG may include magenta image data, yellow image data, and cyan image data. The input control signal CONT may include a master clock signal and a data enable signal. The input control signal CONT may further include a vertical synchronization signal and a horizontal synchronization signal.

The driving controller 200 may generate a first control signal CONT1, a second control signal CONT2, a third control signal CONT3, a fourth control signal CONT4, a fifth control signal CONT5, and a data signal DATA based on the input image data IMG and the input control signal CONT.

The driving controller 200 may generate the first control signal CONT1 for controlling an operation of the gate driver 300 based on the input control signal CONT and output the first control signal CONT1 to the gate driver 300. The first control signal CONT1 may include a vertical start signal and a gate clock signal.

The driving controller 200 may generate the second control signal CONT2 for controlling an operation of the data driver 400 based on the input control signal CONT and output the second control signal CONT2 to the data driver 400. The second control signal CONT2 may include a horizontal start signal and a load signal.

The driving controller 200 may generate the data signal DATA by receiving the input image data IMG and the input control signal CONT. The driving controller 200 may output the data signal DATA to the data driver 400.

The driving controller 200 may generate the third control signal CONT3 for controlling an operation of the emission driver 500 based on the input control signal CONT and output the third control signal CONT3 to the emission driver 500. The third control signal CONT3 may include a vertical start signal and an emission clock signal.

The driving controller 200 may generate the fourth control signal CONT4 for controlling an operation of the readout circuit 600 based on the input control signal CONT and output the fourth control signal CONT4 to the readout circuit 600.

The driving controller 200 may generate the fifth control signal CONT5 for controlling an operation of the reset driver 700 based on the input control signal CONT and output the fifth control signal CONT5 to the reset driver 700.

The gate driver 300 may generate gate signals for driving the pixel gate lines PGL and sensing gate lines SGL in response to the first control signal CONT1 received from the driving controller 200. The gate driver 300 may output the gate signals to the pixel gate lines PGL and the sensing gate lines. For example, the gate driver 300 may sequentially output the gate signals to the pixel gate lines PGL and the sensing gate lines SGL.

The data driver 400 may receive the second control signal CONT2 and the data signal DATA from the driving controller 200. The data driver 400 may generate data voltages obtained by converting the data signal DATA into an analog voltage. The data driver 400 may output the data voltages to a data line DL.

The emission driver 500 may generate emission signals for driving the emission lines EL in response to the third control signal CONT3 received from the driving controller 200. The emission driver 500 may output the emission signals to the emission lines EL. For example, the emission driver 500 may sequentially output the emission signals to the emission lines EL.

The readout circuit 600 may generate sensing information based on sensing signals received from the readout lines RL in response to the fourth control signal CONT4 received from the driving controller 200. For example, the sensing information may correspond to a fingerprint image. The processor or the driving controller 200 may perform a user authentication function using the sensing information provided from the readout circuit 600.

The reset driver 700 may provide a reset signal to the reset lines RSL in response to the fifth control signal CONT5 received from the driving controller 200. In one or more embodiments, the reset driver 700 may be commonly connected to all light sensors LS through the reset line RSL. In one or more other embodiments, the reset driver 700 may be connected to each of the light sensors LS through a plurality of reset lines RSL.

The sub-pixel SP may include a light-emitting element. The light-emitting element may be a light-emitting diode. The light-emitting element may be configured of an organic light-emitting element (organic light-emitting diode), an inorganic light-emitting element (inorganic light-emitting diode), a quantum dot/well light-emitting element (quantum dot/well light-emitting diode), or the like. The light-emitting element may emit light in one of a first color, a second color, and a third color.

The light sensor LS may include a light-receiving element. In one or more embodiments, the light-receiving element may be a photo diode. In one or more other embodiments, the light-receiving element may be configured of a photo transistor.

Light emitted from the light-emitting element may be reflected on a user's fingerprint and applied to a light-receiving element adjacent to the light-emitting element. In addition, the light sensor LS may generate a sensing signal corresponding to a light amount applied to the light-receiving element. The processor or the driving controller 200 may distinguish a valley and a ridge of the fingerprint according to an intensity of the sensing signal, and obtain a fingerprint image of a user through this.

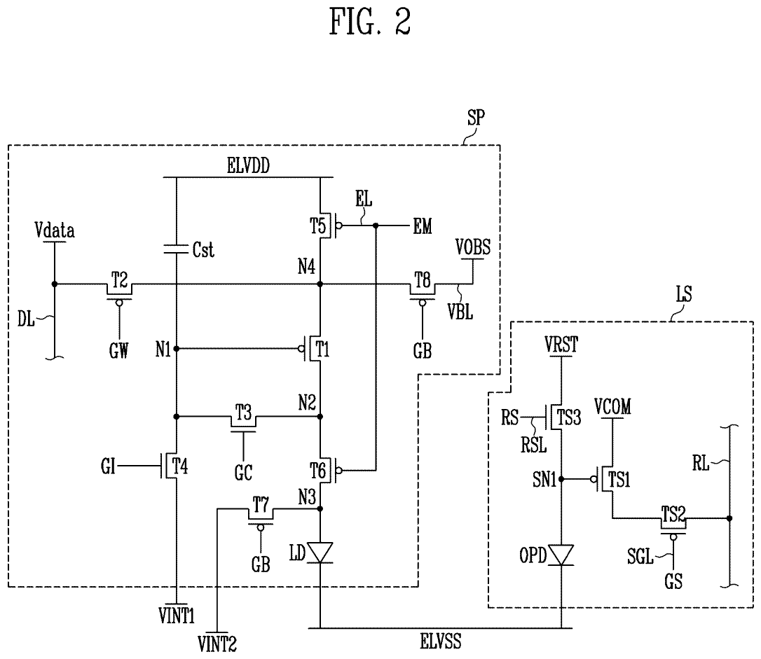

FIG. 2 is a circuit diagram illustrating one or more embodiments of the sub-pixel and the light sensor shown in FIG. 1.

Referring to FIG. 2, the sub-pixel SP may include first to eighth transistors T1 to T8, a storage capacitor Cst, and a light-emitting element LD. The first transistor T1 (e.g., a driving transistor) includes a control electrode connected to a first node N1, a first electrode connected to a fourth node N4, and a second electrode connected to a second node N2. The second transistor T2 includes a control electrode for receiving a write gate signal GW, a first electrode for receiving a data voltage Vdata, and a second electrode connected to the fourth node N4. The third transistor T3 includes a control electrode for receiving a compensation gate signal GC, a first electrode connected to the second node N2, and a second electrode connected to the first node N1. The fourth transistor T4 includes a control electrode for receiving an initialization gate signal GI, a first electrode for receiving a first initialization voltage VINT1, and a second electrode connected to the first node N1. The fifth transistor T5 includes a control electrode for receiving an emission signal EM, a first electrode for receiving a first power voltage ELVDD (for example, a high power voltage), and a second electrode connected to the fourth node N4. The sixth transistor T6 includes a control electrode for receiving the emission signal EM, a first electrode connected to the second node N2, and a second electrode connected to a third node N3. The seventh transistor T7 includes a control electrode for receiving a bias gate signal GB, a first electrode for receiving a second initialization voltage VINT2 (e.g., an anode initialization voltage), and a second electrode connected to the third node N3. The eighth transistor T8 includes a control electrode for receiving the bias gate signal GB, a first electrode for receiving a bias voltage VOBS, and a second electrode connected to the fourth node N4.

Meanwhile, the storage capacitor Cst includes a first electrode for receiving the first power voltage ELVDD and a second electrode connected to the first node N1. The light-emitting element LD includes a first electrode (e.g., an anode electrode) connected to the third node N3 and a second electrode (e.g., a cathode electrode) receiving a second power voltage ELVSS (for example, a low power voltage). The data voltage Vdata may be transmitted through the data line DL, and the emission signal EM may be transmitted through an emission line EL. In addition, the bias voltage VOBS may be transmitted through a bias voltage line VBL.

However, the disclosure is not limited to a structure of the sub-pixel SP. For example, each of the sub-pixels SP may have a 3T1C structure configured of three transistors and one capacitor, a 5T2C structure configured of five transistors and two capacitors, a 7T1C structure configured of seven transistors and one capacitor, a 9T1C structure configured of nine transistors and one capacitor, or the like.

One or more of the first to seventh transistors T1, T2, T3, T4, T5, T6, or T7 may be implemented as p-channel metal oxide semiconductor (PMOS) transistors. In this case, a low voltage level may be an activation level, and a high voltage level may be an inactivation level. For example, when a signal applied to a control electrode of the PMOS transistor has the low voltage level, the PMOS transistor may be turned on. For example, when the signal applied to the control electrode of the PMOS transistor has the high voltage level, the PMOS transistor may be turned off.

However, the disclosure is not limited thereto. For example, one or more of the first to seventh transistors T1, T2, T3, T4, T5, T6, or T7 may be implemented as n-channel metal oxide semiconductor (NMOS) transistors. In this case, a low voltage level may be an inactivation level, and a high voltage level may be an activation level. For example, when a signal applied to a control electrode of the NMOS transistor has the low voltage level, the NMOS transistor may be turned off. For example, when the signal applied to the control electrode of the NMOS transistor has the high voltage level, the NMOS transistor may be turned on. That is, an activation level and an inactivation level may be determined according to a type of a transistor.

For example, in an initialization period, the initialization gate signal GI may have an activation level and the fourth transistor T4 may be turned on. Accordingly, the first initialization voltage VINT1 may be applied to the first node N1. That is, the control electrode (e.g., the storage capacitor Cst) of the first transistor T1 may be initialized.

For example, in a threshold voltage compensation period, the compensation gate signal GC may have an activation level, and the third transistor T3 may be turned on. Accordingly, the first transistor T1 may be diode connected.

For example, in a data write period, the write gate signal GW may have an activation level, and the second transistor T2 and the third transistor T3 may be turned on. Accordingly, a voltage of the first node N1 may have a voltage in which a threshold voltage of the first transistor T1 is compensated for a data signal. Therefore, the data voltage Vdata may be written to the storage capacitor Cst.

For example, in an anode initialization period, the bias gate signal GB may have an activation level, and the seventh transistor T7 may be turned on. Accordingly, the second initialization voltage VINT2 may be applied to the first electrode (e.g., the anode electrode) of the light-emitting element LD.

For example, in an emission period, the emission signal EM may have an activation level, and the fifth transistor T5 and the sixth transistor T6 may be turned on. Accordingly, the first power voltage ELVDD may be applied to the first transistor T1 to generate a driving current, and the driving current may be applied to the light-emitting element LD. That is, the light-emitting element LD may emit light with a luminance corresponding to the driving current.

Meanwhile, the light sensor LS includes a first sensing transistor TS1, a second sensing transistor TS2, a third sensing transistor TS3, and a light-receiving element OPD. The first sensing transistor TS1 generates a sensing signal. The second sensing transistor TS2 transmits the sensing signal to the readout line RL in response to the sensing gate signal GS. The third sensing transistor TS2 initializes a control node of the first sensing transistor TS1 in response to a reset signal RST. The light-receiving element OPD is connected to the control node of the first sensing transistor TS1. For example, the sensing signal may be a current generated by the first sensing transistor TS1.

For example, the first sensing transistor TS1 includes a control electrode connected to a first sensing node SN1, a first electrode for receiving a common voltage VCOM, and a second electrode connected to a first electrode of the second sensing transistor TS2. The second sensing transistor TS2 includes a control electrode for receiving the sensing gate signal GS, the first electrode connected to the second electrode of the first sensing transistor TS1, and a second electrode connected to the readout line RL. The light-receiving element OPD includes a first electrode connected to the first sensing node SN1 and a second electrode for receiving the second power voltage ELVSS (for example, the low power voltage). The third sensing transistor TS3 may include a control electrode for receiving the reset signal RST, a first electrode for receiving a reset voltage VRST, and a second electrode connected to the first sensing node SN1.

For example, in one or more embodiments, the first and second sensing transistors TS1 and TS2 may be implemented as PMOS transistors, and the third sensing transistor TS3 may be implemented as an NMOS transistor. However, the disclosure is not limited thereto.

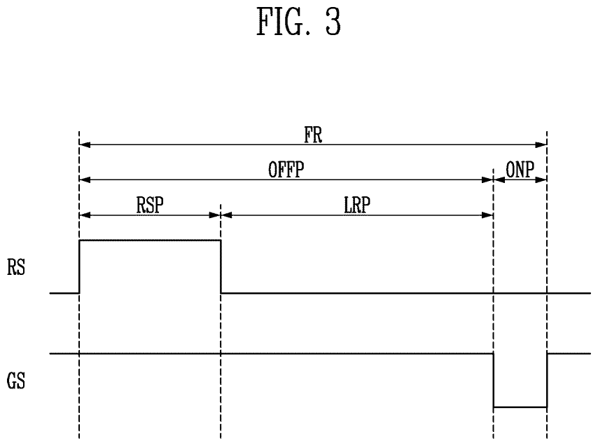

FIG. 3 is a timing diagram illustrating an example in which the display device of FIG. 1 drives the light sensor.

Referring to FIGS. 2 and 3 together, one frame FR includes a sensing on period ONP in which the sensing gate signal GS has an activation level, and a sensing off period OFFP in which the sensing gate signal GS has an inactivation level. For example, as shown in FIG. 2, when the second sensing transistor TS2 is a PMOS transistor, the activation level of the sensing gate signal GS may be a low voltage level, and the inactivation level of the sensing gate signal GS may be a high voltage level.

The reset signal RS may have an activation period (e.g., a reset period RSP) in the sensing off period OFFP in which the sensing gate signal GS has the inactivation level. In addition, the reset signal RS may have an inactivation period (e.g., a light-receiving period LRP) in the sensing off period OFFP. Here, the activation period is a period with an activation level, and the inactivation period is a period with an inactivation level.

For example, as shown in FIG. 2, if the third sensing transistor TS3 is an NMOS transistor, the activation level of the reset signal RS may be a high voltage level, and the inactivation level may be a low voltage level.

In one or more embodiments, the reset period RSP is at a start of the sensing off period OFFP, but the disclosure is not limited thereto.

For example, in the reset period RSP, the reset signal RS may have the activation level, and the sensing gate signal GS may have the inactivation level. Accordingly, the third sensing transistor TS3 may be turned on, and the second sensing transistor TS2 may be turned off. In addition, the reset voltage VRST may be applied to the first sensing node SN1. That is, the first sensing node SN1 and the first electrode of the light-receiving element OPD may be initialized.

For example, in the light-receiving period LRP, the reset signal RS and the sensing gate signal GS may have the inactivation level. Accordingly, the second sensing transistor TS2 and the third sensing transistor TS3 may be turned off. In addition, when light is applied, the light-receiving element OPD may generate a current in a direction of the first sensing node SN1, and a voltage of the first sensing node SN1 may be decreased. Accordingly, an intensity of the sensing signal generated in the sensing on period ONP to be described later may be changed. In addition, because a light amount applied to the light-receiving element OPD is changed according to the valley and the ridge of the fingerprint, the intensity of the sensing signal may be changed according to the valley and the ridge of the fingerprint.

For example, in the sensing on period ONP, the reset signal RS may have the inactivation level, and the sensing gate signal GS may have the activation level. Accordingly, the second sensing transistor TS2 may be turned on, and the third sensing transistor TS3 may be turned off. In addition, the first sensing transistor TS1 may generate a sensing signal corresponding to a gate-source voltage. The sensing signal may be applied to the readout circuit through the readout line RL.

Referring to FIGS. 2 and 3, in one or more embodiments, the common voltage VCOM may be the second initialization voltage VINT2. For example, the common voltage VCOM and the second initialization voltage VINT2 may be about −3.5 V.

In one or more embodiments, the reset voltage VRST may be less than the common voltage VCOM. For example, the common voltage VCOM may be about −3.5 V, and the reset voltage VRST may be about −4.5 V.

In one or more embodiments, a bias voltage VBIAS may be the second power voltage ELVSS. For example, the bias voltage VBIAS and the second power voltage ELVSS may be about −2.5 V.

Referring to FIG. 2, the sub-pixel SP and the light sensor LS are configured as separate circuits. In this case, increasing resolution of the display panel 100 may be difficult.

According to one or more other embodiments of the disclosure, the light sensor is integrated into the sub-pixel included in the display panel. According to the disclosure, the sub-pixel integrated with the light sensor may use fewer transistors than the sub-pixel and the light sensor implemented as separate circuits. Therefore, a display panel of high-resolution may be implemented.

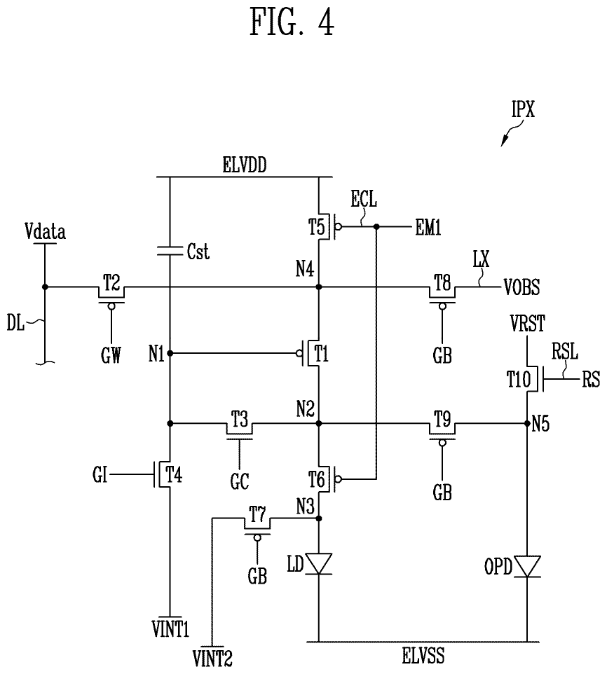

FIG. 4 is a circuit diagram illustrating one or more embodiments of a sub-pixel according to one or more embodiments of the disclosure.

Referring to FIG. 4, the sub-pixel IPX includes first to tenth transistors T1 to T10, a storage capacitor Cst, a light-emitting element LD, and a light-receiving element OPD. In FIG. 4, a connection relationship of the first to eighth transistors T1 to T8, the storage capacitor Cst, and the light-emitting element LD is the same as that of the sub-pixel SP of FIG. 2. Therefore, an overlapping description thereof is omitted.

The ninth transistor T9 includes a control electrode connected to the bias gate signal GB, a first electrode connected to a fifth node N5, and a second electrode connected to the second node N2. The tenth transistor T10 includes a control electrode for receiving the reset signal RST, a first electrode for receiving the reset voltage VRST, and a second electrode connected to the fifth node N5. The light-receiving element OPD includes a first electrode connected to the fifth node N5, and a second electrode for receiving the second power voltage ELVSS (for example, the low power voltage).

Meanwhile, referring to FIG. 4, the first electrode of the eighth transistor T8 is connected to a transmission/reception line LX. The transmission/reception line LX may receive the bias voltage VOBS, or may transmit a sensing signal corresponding to a current corresponding to a light amount applied to the light-receiving element OPD to the readout circuit through the readout line RL.

As shown in FIG. 4, a light sensor is integrated in the sub-pixel IPX according to one or more embodiments of the disclosure. Accordingly, fewer transistors may be used compared to the one or more embodiments corresponding to FIG. 2, which individually implements the sub-pixel and the light sensor.

For example, the sub-pixel IPX according to one or more embodiments of the disclosure may include at least one transistor that is used both in an operation in which the light-emitting element LD generates light, and in an operation of sensing light applied to the light-receiving element OPD. According to the one or more embodiments corresponding to FIG. 4, the first transistor T1 is used in the operation in which the light-emitting element LD generates light and the operation of sensing light applied to the light-receiving element OPD, and is also used in an operation of sensing light applied to the light-receiving element OPD.

For example, the first transistor T1 controls a current flowing through the light-emitting element LD. In this case, the first transistor T1 may operate as described for the sub-pixel SP of FIG. 2.

Meanwhile, the first transistor T1 may transmit the sensing signal corresponding to the light amount applied to the light-receiving element OPD. That is, when light is applied to the light-receiving element OPD during a light-receiving period, the light-receiving element OPD may generate a current in a direction of the fifth node N5, and a voltage of the fifth node N5 may be decreased. Thereafter, as the ninth transistor T9, the first transistor T1, and the eighth transistor T3 are turned on, a current path is formed between the transmission/reception line LX and the fifth node N5. That is, a current corresponding to the voltage of the fifth node N5 may flow through the transmission/reception line LX, and the readout circuit may determine the light amount applied to the light-receiving element OPD corresponding to the voltage of the fifth node N5 through the current flowing through the transmission/reception line LX.

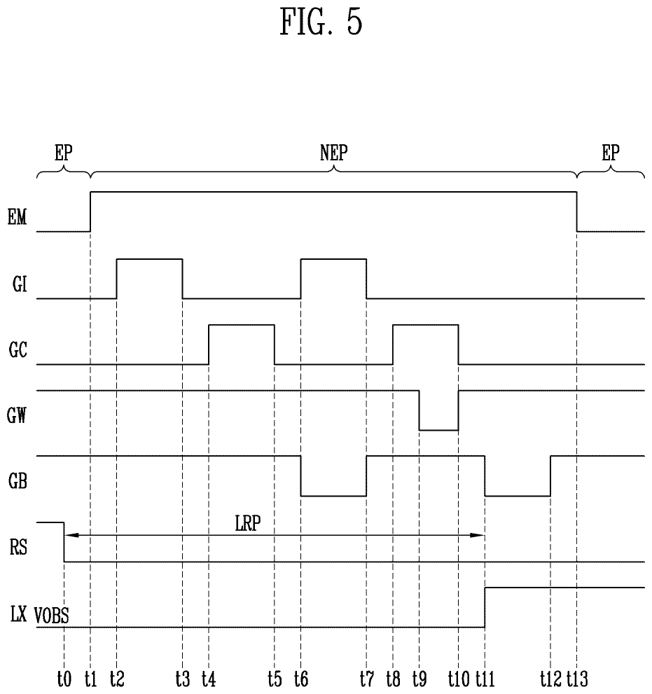

FIG. 5 is a timing diagram illustrating one or more embodiments of a method of driving the sub-pixel shown in FIG. 4.

In FIG. 5, an operation of the sub-pixel may include an emission period EP and a non-emission period NEP. The emission period EP may correspond to a low level period (e.g., an active period) of the emission signal EM, and the non-emission period NEP may correspond to a high level period (e.g., an inactive period) of the emission signal EM. For example, the non-emission period NEP may correspond to a period t1 to t13.

For example, at a time t0 of the emission period EP, the reset signal RS may be activated to a low level. Accordingly, the light-receiving period LRP may start from the time t0.

Meanwhile, during a period t2 to t3 of the non-emission period NEP, the initialization gate signal GI may be activated to a high level, and the fourth transistor T4 is turned on to initialize a voltage of the first node N1.

During a period t4 to t5, the compensation gate signal GC is activated to a high level. Accordingly, the third transistor T3 is turned on, and a threshold voltage of the first transistor T1 is compensated.

During a period t6 to t7, the initialization gate signal GI may be activated to a high level, and the bias gate signal GB may be activated to a low level. Accordingly, the fourth transistor T4 may be turned to initialize the first node N1, and the eighth transistor T8 may be turned on to transmit the bias voltage VOBS applied to the transmission/reception line LX to the fourth node N4.

During a period t8 to t10, the compensation gate signal GC is activated to a high level. Accordingly, the third transistor T3 is turned on, and the threshold voltage of the first transistor T1 is compensated. During a period t9 to t10, the write gate signal GW may be activated to a low level, the second transistor T2 may be turned on, and because the third transistor T3 is in a state in which the third transistor T3 is turned on, the first transistor T1 may be diode-connected. Accordingly, the voltage of the first node N1 may have a voltage in which the threshold voltage of the first transistor T1 is compensated for the data signal. Therefore, the data voltage Vdata may be written to the storage capacitor Cst. During a period t11 to t12, the bias gate signal GB is activated to a low level, and thus, the seventh transistor T7 is turned on. Accordingly, an anode electrode voltage of the light-emitting element LD is initialized. That is, when the sub-pixel IPX operates as a light-emitting element, a data write operation of the sub-pixel is performed during the period t11 to t12.

Meanwhile, when the sub-pixel IPX operates as a light-receiving element, the transmission/reception line LX is connected to the readout line RL during the period t11 to t12. In addition, during the period t11 to t12, the bias gate signal GB is activated to a low level, and thus the eighth and ninth transistors T8 and T9 are turned on. Therefore, a current path may be formed from the fifth node N5 to the transmission/reception line LX through the second node N2 and the fourth node N4. That is, when the sub-pixel IPX operates as a light-receiving element, a current corresponding to the light amount applied to the light-receiving element OPD during the period t11 to t12 flows to the transmission/reception line LX. Therefore, in FIG. 5, a voltage of the transmission/reception line LX is shown to increase above the bias voltage VOBS after a time t11.

However, the timing diagram shown in FIG. 5 is only an example, and the method of operating the sub-pixel shown in FIG. 4 is not limited thereto. The sub-pixel shown in FIG. 4 may operate in various methods different from that of FIG. 5.

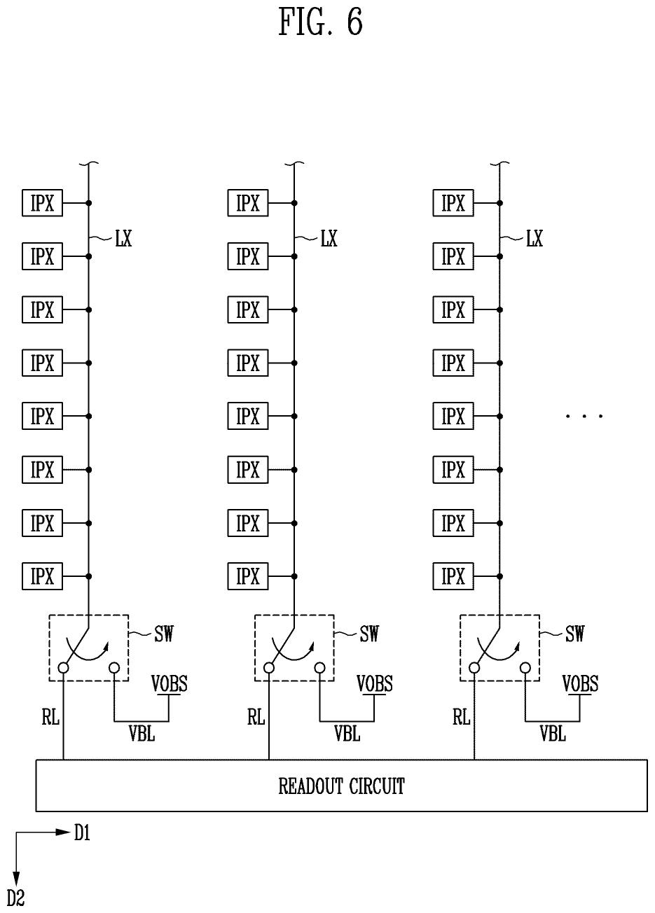

FIG. 6 is a diagram illustrating one or more embodiments of a connection structure of the transmission/reception line LX.

Referring to FIG. 6, among components of the display device, a portion of the sub-pixels included in the display area in the display panel, and a readout circuit connected thereto, are shown. For example, in the one or more embodiments corresponding to FIG. 6, sub-pixels IPX corresponding to three columns are shown.

As described above with reference to FIG. 4, the sub-pixel IPX according to one or more embodiments of the disclosure may include the transmission/reception line LX. When the sub-pixel IPX performs a light-emitting operation, the transmission/reception line LX may supply the bias voltage VOBS to the sub-pixel IPX, and when the sub-pixel IPX performs a light-sensing operation, the transmission/reception line LX may transmit the current corresponding to the light amount applied to the light-receiving element OPD to the readout circuit through the readout line RL. To this end, the display device according to one or more embodiments of the disclosure may include switches SW configured to selectively connect the readout line RL or the bias voltage line VBL to the transmission/reception line LX.

The switches SW shown in FIG. 6 may operate individually based on a control signal to which the switches SW are respectively connected. For example, some of the switches SW among the plurality of switches SW may connect the transmission/reception line LX to the readout line RL, and remaining switches SW may connect the transmission/reception line LX to the bias voltage line VBL. In this case, some of the sub-pixels IPX corresponding to one row may operate as a light sensor, and remaining sub-pixels may perform a light-emitting operation. If suitable, switches SW of a column corresponding to a fingerprint recognition area may connect the transmission/reception line LX to the readout line RL, and remaining switches SW may connect the transmission/reception line LX to the bias voltage line VBL. In this case, the sub-pixels IPX corresponding to the fingerprint recognition area may operate as the light sensor, and the remaining sub-pixels may perform a light-emitting operation.

According to the one or more embodiments corresponding to FIG. 6, all of the sub-pixels included in the display device are shown as being implemented as the sub-pixels shown in FIG. 4, that is, sub-pixels in which the light sensor is integrated. In this case, the number of light-emitting elements and the number of light-receiving elements included in the display panel of the display device may be the same. Meanwhile, according to the one or more embodiments corresponding to FIG. 6, the transmission/reception line LX may be provided for each column of all sub-pixels.

However, the disclosure is not limited thereto, and a portion of the sub-pixels included in the display device may be implemented as the sub-pixel IPX shown in FIG. 4, and another of the sub-pixels may be implemented as the sub-pixel SP shown in FIG. 2.

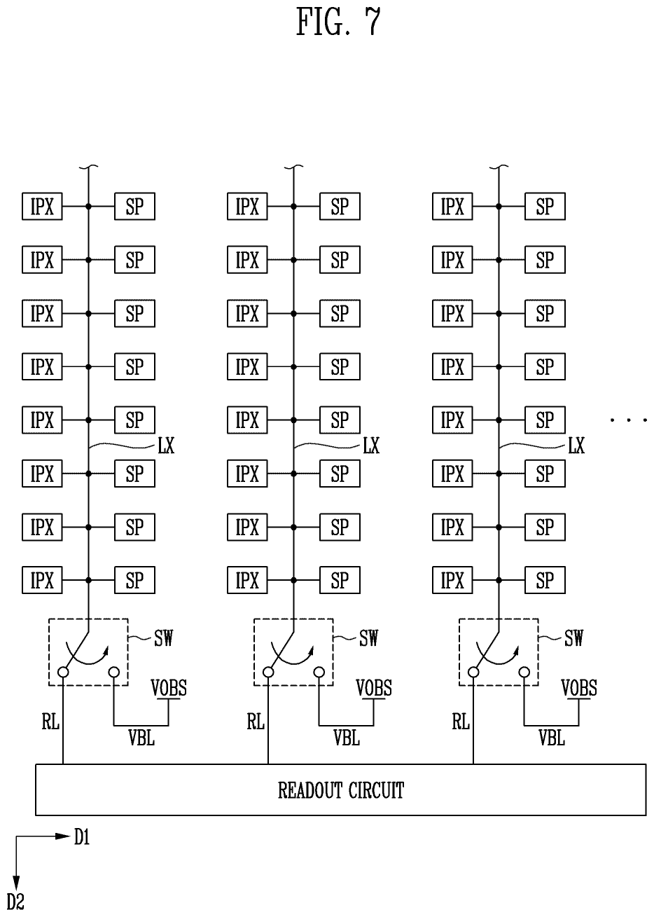

FIG. 7 is a drawing illustrating one or more other embodiments of the connection structure of the transmission/reception line LX.

Referring to FIG. 7, among components of the display device, a portion of the sub-pixels included in the display area in the display panel, and a readout circuit connected thereto, are shown. For example, in the one or more embodiments corresponding to FIG. 6, sub-pixels corresponding to six columns are shown.

In FIG. 7, one transmission/reception line LX is shown as being shared by sub-pixels corresponding to two columns. For example, in FIG. 7, one transmission/reception line LX is shared by sub-pixels IPX corresponding to one column and sub-pixels SP corresponding to another column. Each of the sub-pixels IPX may be the sub-pixel IPX shown in FIG. 4, and each of the sub-pixels SP may be the sub-pixel SP shown in FIG. 2, for example.

Similarly to that described above with reference to FIG. 5, the sub-pixel IPX according to one or more embodiments of the disclosure may include the transmission/reception line LX. When the sub-pixel IPX performs a light-emitting operation, the transmission/reception line LX may supply the bias voltage VOBS to the sub-pixel IPX, and when the sub-pixel IPX performs a light-sensing operation, the transmission/reception line LX may transmit the current corresponding to the light amount applied to the light-receiving element OPD to the readout circuit through the readout line RL. To this end, the display device according to one or more embodiments of the disclosure may include switches SW configured to selectively connect the readout line RL or the bias voltage line VBL to the transmission/reception line LX.

According to the one or more embodiments corresponding to FIG. 7, half of the sub-pixels included in the display device is implemented as the sub-pixel IPX shown in FIG. 4, that is, the sub-pixel in which the light sensor is integrated, and a remaining half is implemented as the sub-pixels SP shown in FIG. 2. In this case, a ratio of the number of light-emitting elements to the number of light-receiving elements included in the display panel of the display device may be 2:1.

However, the disclosure is not limited thereto, and the ratio of the number of sub-pixels IPX shown in FIG. 4 and the number of sub-pixels SP shown in FIG. 2 among the sub-pixels included in the display device may be variously determined.

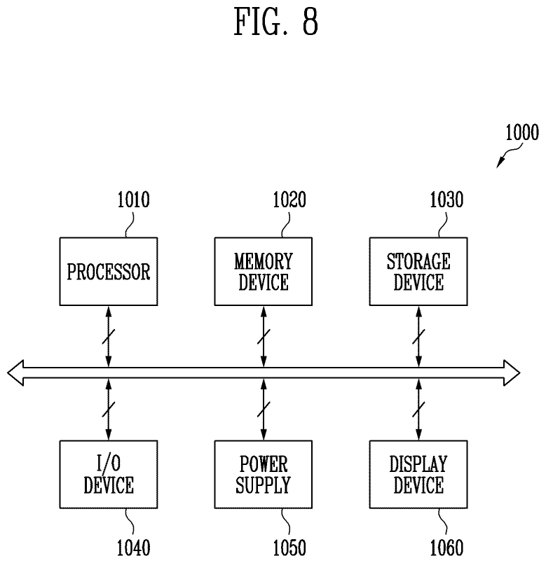

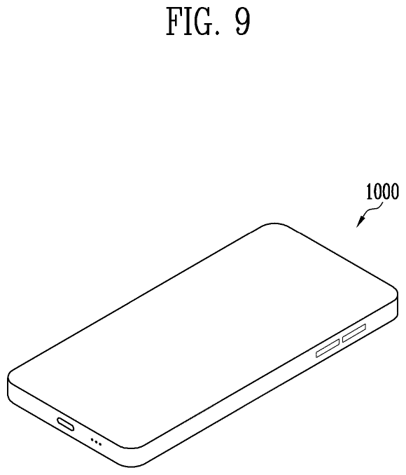

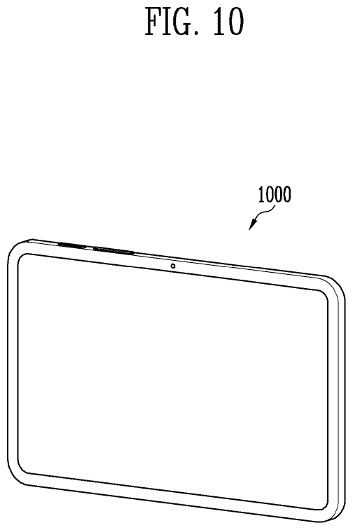

FIG. 8 is a block diagram illustrating an electronic device according to embodiments of the disclosure, FIG. 9 is a diagram illustrating one or more embodiments in which the electronic device of FIG. 8 is implemented as a smartphone, and FIG. 10 is a diagram illustrating one or more embodiments in which the electronic device of FIG. 8 is implemented as a tablet PC.

Referring to FIGS. 8 to 10, the electronic device 1000 may include a processor 1010, a memory device 1020, a storage device 1030, an input/output device 1040, a power supply 1050, and a display device 1060. At this time, the display device 1060 may be the display device of FIG. 1. In addition, the electronic device 1000 may further include several ports capable of communicating with a video card, a sound card, a memory card, a USB device, or the like, or communicating with other systems. In one or more embodiments, as shown in FIG. 9, the electronic device 1000 may be implemented as a smart phone. In one or more other embodiments, as shown in FIG. 10, the electronic device 1000 may be implemented as a tablet PC. However, the electronic device 1000 is not limited thereto. For example, the electronic device 1000 may be implemented as a mobile phone, a video phone, a smart pad, a smart watch, a vehicle navigation device, a computer monitor, a notebook computer, a head mounted display device, or the like.

The processor 1010 may perform specific calculations or tasks. According to one or more embodiments, the processor 1010 may be a microprocessor, a central processing unit, an application processor, or the like. The processor 1010 may be connected to other components through an address bus, a control bus, a data bus, or the like. According to one or more embodiments, the processor 1010 may also be connected to an expansion bus, such as a peripheral component interconnect (PCI) bus.

The memory device 1020 may store data suitable for an operation of the electronic device 1000. For example, the memory device 1020 may include a non-volatile memory device, such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM), and a ferroelectric random access memory (FRAM) device, a volatile memory device, such as a dynamic random access memory (DRAM) device, a static random access memory (SRAM) device, and a mobile DRAM device, and/or the like.

The storage device 1030 may include a solid state drive (SSD), a hard disk drive (HDD), a CD-ROM, and the like.

The input/output device 1040 may include an input means, such as a keyboard, a keypad, a touch pad, a touch screen, and a mouse, and an output means, such as a speaker and a printer. According to one or more embodiments, the display device 1060 may be included in the input/output device 1040.

The power supply 1050 may supply power suitable for an operation of the electronic device 1000. For example, the power supply 1050 may be a power management integrated circuit (PMIC).

The display device 1060 may display an image corresponding to visual information of the electronic device 1000. At this time, the display device 1060 may be an organic light-emitting display device or a quantum dot light-emitting display device, but is not limited thereto. The display device 1060 may be connected to other components through the buses or other communication links.

The electronic device 1000 according to one or more embodiments is a device that displays a moving image and/or a still image. The electronic device 1000 may be applied to portable electronic devices such as mobile phones, smartphones, tablet personal computers (PCs), mobile communication terminals, electronic notebooks, electronic books, portable multimedia players (PMPs), navigations, and ultra-mobile PCs (UMPCs). For example, the electronic device 1000 may be applied to a display unit of a television, a laptop computer, a monitor, a billboard, or the Internet of Things (IoT). Alternatively, in one or more embodiments, the electronic device 1000 may be applied to a smartwatch, a watch phone, a virtual reality (VR) device, an augmented reality (AR) device, and/or a head-mounted display device (HMD) (e.g., for implementing virtual reality and/or augmented reality).

Although specific embodiments and application examples are described herein, other embodiments and variations may be derived from the above description. Therefore, the spirit of the disclosure is not limited to these embodiments, but extends to the scope of the claims set forth below, various obvious modifications, and equivalents.

What is claimed is:

1. A pixel comprising:
a light-emitting element;
a first transistor connected between a first power voltage and the light-emitting element, and configured to control a current flowing through the light-emitting element; and
a light-receiving element connected between a fifth node and a second power voltage,
wherein a voltage of the fifth node corresponds to a light amount applied to the light-receiving element, and
wherein a current transmitted to a readout line through the first transistor corresponds to the voltage of the fifth node.

2. The pixel according to claim 1, wherein the first transistor comprises a control electrode connected to a first node, a first electrode connected to a fourth node, and a second electrode connected to a second node, and
wherein the pixel further comprises:
a ninth transistor connected between the second node and the fifth node; and
a tenth transistor connected between a reset voltage and the fifth node.

3. The pixel according to claim 2, further comprising an eighth transistor connected between the fourth node and the readout line.

4. The pixel according to claim 2, further comprising a second transistor connected between the fourth node and a data line.

5. The pixel according to claim 2, further comprising a storage capacitor connected between the first power voltage and the first node.

6. The pixel according to claim 2, further comprising a third transistor connected between the first node and the second node.

7. The pixel according to claim 2, wherein the light-emitting element comprises an anode electrode connected to a third node, and a cathode electrode connected to the second power voltage, and
wherein the pixel further comprises:
a fifth transistor connected between the first power voltage and the fourth node; and
a sixth transistor connected between the second node and the third node.

8. The pixel according to claim 7, further comprising:
a fourth transistor connected between the first node and a first initialization voltage; and
a seventh transistor connected between the third node and a second initialization voltage.

9. A display device comprising:
a display panel comprising pixels; and
a display panel driver configured to drive the display panel,
wherein the pixels comprise:
a light-emitting element;
a first transistor connected between a first power voltage and the light-emitting element, and configured to control a current flowing through the light-emitting element; and
a light-receiving element connected between a fifth node and a second power voltage,
wherein a voltage of the fifth node is changed according to a light amount applied to the light-receiving element, and a current corresponding to the voltage of the fifth node is transmitted to the display panel driver through the first transistor.

10. The display device according to claim 9, wherein the first transistor comprises a control electrode connected to a first node, a first electrode connected to a fourth node, and a second electrode connected to a second node, and
wherein the pixels further comprise:
a ninth transistor connected between the second node and the fifth node; and
a tenth transistor connected between a reset voltage and the fifth node.

11. The display device according to claim 10, further comprising an eighth transistor connected between the fourth node and a corresponding transmission/reception line.

12. The display device according to claim 11, further comprising:
switches configured to selectively connect a transmission/reception line corresponding to one or more of the pixels to one of a bias voltage line or a readout line corresponding to the one or more pixels; and
a readout circuit connected to the readout line.

13. The display device according to claim 11, wherein the pixels further comprise a second transistor connected between the fourth node and a data line.

14. The display device according to claim 11, wherein the pixels further comprise a storage capacitor connected between the first power voltage and the first node.

15. The display device according to claim 11, wherein the pixels further comprise a third transistor connected between the first node and the second node.

16. The display device according to claim 11, wherein the light-emitting element comprises an anode electrode connected to a third node, and a cathode electrode connected to the second power voltage, and
wherein the pixels further comprise:
a fifth transistor connected between the first power voltage and the fourth node; and
a sixth transistor connected between the second node and the third node.

17. The display device according to claim 16, wherein the pixels further comprise:
a fourth transistor connected between the first node and a first initialization voltage; and
a seventh transistor connected between the third node and a second initialization voltage.

18. The display device according to claim 17, wherein the pixels further comprise a second transistor connected between the fourth node and a data line,
wherein the pixels further comprise a third transistor connected between the first node and the second node,
wherein the first, second, fifth, sixth, seventh, eighth, and ninth transistors comprise PMOS transistors, and
wherein the third, fourth, and tenth transistors comprise NMOS transistors.

19. An electronic device comprising:
a processor configured to provide input image data to a display device that is configured to display an image based on the input image data; and
a power supply configured to supply power to the display device,
wherein the display device comprises:
a display panel comprising pixels; and
a display panel driver configured to drive the display panel,
wherein the pixels comprise:
a light-emitting element;
a first transistor connected between a first power voltage and the light-emitting element, and configured to control a current flowing through the light-emitting element; and
a light-receiving element connected between a fifth node and a second power voltage,
wherein a voltage of the fifth node is changed according to a light amount applied to the light-receiving element, and
wherein a current corresponding to the voltage of the fifth node is transmitted to the display panel driver through the first transistor.

20. The electronic device according to claim 19, wherein the first transistor comprises a control electrode connected to a first node, a first electrode connected to a fourth node, and a second electrode connected to a second node, and
wherein the pixels further comprise:
a ninth transistor connected between the second node and the fifth node; and
a tenth transistor connected between a reset voltage and the fifth node.
